(19) United States
(12) Patent Application Publication
(10) Pub. No.: US 2023/0154690 A1
(43) Pub. Date: May 18, 2023

(54) Semiconductor Photoelectrode

(71) Applicant: Nippon Telegraph and Telephone Corporation, Tokyo (JP)

(72) Inventors: Yoko Ono, Musashino-shi, Tokyo (JP); Yuya Uzumaki, Musashino-shi, Tokyo (JP); Sayumi Sato, Musashino-shi, Tokyo (JP); Takeshi Komatsu, Musashino-shi, Tokyo (JP)

(21) Appl. No.: 17/917,501

(22) PCT Filed: May 19, 2020
(86) PCT No.: PCT/JP2020/019728

§ 371 Date: Oct. 6, 2022

(51) Int. Cl. H01G 9/20; H01G 9/048

(52) U.S. Cl. CPC H01G 9/205; H01G 9/048

(57) ABSTRACT

A semiconductor photoelectrode that is to be located in an aqueous solution to cause a decomposition reaction of the aqueous solution upon being irradiated with light, the semiconductor photoelectrode including: a semiconductor layer that is formed on an insulative or conductive substrate and is provided with a plurality of protrusion structures that protrude in one direction that is opposite a direction in which the substrate is located; a catalyst layer that is continuously laminated on the surface of the semiconductor layer; and a wire that is electrically connected to the semiconductor layer.

### TECHNICAL FIELD

The present invention relates to a semiconductor photoelectrode.

### BACKGROUND ART

There are conventionally known photocatalysts that exhibit a catalytic function upon being irradiated with light and induce chemical reactions of an oxidation target substance or reduction target substance. For example, research is being conducted on a technique for using sunlight to generate hydrogen from water without the generation of carbon dioxide.

To improve the quantum yield of photocatalytic reactions with the above photocatalysts, spatial separation of photoexcited electron-hole pairs in the photocatalysts and transfer of holes or electrons to sites that promote oxidation or reduction reactions (an oxidation reaction site or a reduction reaction site) provided to inhibit the reverse reaction of a reaction intermediate or a product are required.

Therefore, in order to suppress the reverse reaction of a reaction intermediate or a product, an electrode-based method has been proposed to control the arrangement of an oxidation reaction site and a reduction reaction site. For example, in NPLs 1 and 2, in order to improve the efficiency of the carbon dioxide reduction reaction, a carbon dioxide reduction reaction site and a water oxidation reaction site are separately provided as a metal anode plate and a cathode plate of gallium nitride-based semiconductor thin film electrode with a photocatalytic function, respectively, and both electrodes are electrically connected so that electrons flow from the cathode plate to the anode plate. In addition, the anode plate and the cathode plate are immersed in an electrolyte, and the electrodes are separated from each other by an ion-exchange membrane so that reverse reactions can be suppressed.

### CITATION LIST

### Non Patent Literature

[NPL 1] Satoshi Yotsuhashi and other six authors, “Photo-induced CO2 Reduction with GaN Electrode in Aqueous System”, Applied Physics Express 4 (2011) 117101, 2011 The Japan Society of Applied Physics, p. 117101-1-p. 117101-3
[NPL 2] Satoshi Yotsuhashi and other seven authors, “Highly efficient photochemical HCOOH production from CO2 and water using an inorganic system”, AIP Advance 2 (2012) 042160, p. 042160-1-p. 042160-5
[NPL 3] Satoshi Yotsuhashi and other six authors, “Enhanced CO2 reduction capability in an AlGaN/GaN photoelectrode”, Applied Physics Letter 100 (2012) 243904, 2012 American Institute of Physics, p. 243904-1-p. 243904-3

### SUMMARY OF THE INVENTION

### Technical Problem

However, the gallium nitride semiconductor thin film electrode deteriorates due to self-oxidation caused by light irradiation. Therefore, there is the problem in that the rate of hydrogen production declines with the time of light irradiation, and a stable high photocurrent cannot be obtained, which makes it impossible to absorb light efficiently. Therefore, in NPL 3, nickel oxide is supported on the surface of the gallium nitride semiconductor thin film electrode as an auxiliary catalyst, so that holes generated on the semiconductor as a result of light irradiation are collected by the auxiliary catalyst, and thus self-oxidation is suppressed. However, the semiconductor surface is exposed except for the area on which the auxiliary catalyst is supported. Therefore, it is difficult to reliably suppress semiconductor deterioration caused by self-oxidation.

The present invention is made considering the above-described situation, and aims to provide a technique for suppressing deterioration and improving light absorption efficiency in a semiconductor photoelectrode, such as a gallium nitride semiconductor thin film electrode.

### Means for Solving the Problem

A semiconductor photoelectrode according to one aspect of the present invention is A semiconductor photoelectrode that causes a decomposition reaction of an aqueous solution in the aqueous solution upon being irradiated with light, the semiconductor photoelectrode including: a semiconductor layer that is formed on an insulative or conductive substrate and is provided with a plurality of protrusion structures that protrude in one direction that is opposite a direction in which the substrate is located; a catalyst layer that is continuously laminated on the surface of the semiconductor layer; and a wire that is electrically connected to the semiconductor layer.

### Effects of the Invention

According to the present invention, it is possible to provide a technique that makes it possible to suppress deterioration and improve light absorption efficiency in a semiconductor photoelectrode.

### BRIEF DESCRIPTION OF DRAWINGS

FIG. 1 is a diagram showing a cross-sectional structure of a semiconductor photoelectrode according to Example 1.

FIG. 2 is a diagram showing procedures for manufacturing the semiconductor photoelectrode according to Example 1.

FIG. 3 is a diagram showing a cross-sectional structure of a wiring portion of the semiconductor photoelectrode according to Example 1.

FIG. 4 is a diagram showing a configuration of an oxidation-reduction reaction apparatus according to Example 1.

FIG. 5 is a diagram showing a cross-sectional structure of a semiconductor photoelectrode according to Comparative Example 1.

FIG. 6 is a diagram showing a cross-sectional structure of a semiconductor photoelectrode according to Modification 1 of Example 1.

FIG. 7 is a diagram showing a cross-sectional structure of a semiconductor photoelectrode according to Modification 2 of Example 1.

### DESCRIPTION OF EMBODIMENTS

Hereinafter, an embodiment of the present invention will be described with reference to the drawings. The present invention is not limited to the following embodiment, and may be modified without departing from the spirit of the present invention.

### Summary of the Invention

The present invention relates to the structure of a semiconductor thin film (photocatalyst) that exhibits a catalytic function for oxidation reaction and reduction reaction using light such as sunlight, to efficiently cause chemical reactions of an oxidation target substance and a reduction target substance, and improves the light absorption efficiency of materials under light irradiation, and a semiconductor device using such a semiconductor thin film. The present invention also belongs to solar energy conversion technique and fuel generation technique.

As described above, a gallium nitride semiconductor thin film electrode undergoes self-oxidation upon being irradiated with light. Therefore, in order to maintain a stable high hydrogen production rate and obtain a stable high photocurrent by using a compound semiconductor material such as a gallium nitride semiconductor, which is easily self-oxidized due to light, as the oxidation electrode, it is desirable to increase the surface area of the oxidation electrode that is to be irradiated with light, and to form a protective film on the surface of the oxidation electrode to efficiently extract holes generated as a result of light irradiation, from the oxidation electrode.

Therefore, according to the present invention, protrusion structures are formed on the surface of the semiconductor layer used as the oxidation electrode or the reduction electrode, and the surface of the semiconductor layer is coated with a catalyst layer of oxide semiconductor. Since the protrusion structures are formed on the surface of the semiconductor layer, the surface area of the semiconductor layer is increased, and light can be efficiently absorbed. Also, the surface of the semiconductor layer is covered with the catalyst layer, and therefore holes generated in the semiconductor layer as a result of light irradiation can be efficiently collected by the catalyst layer, and oxidation of the semiconductor layer can be suppressed. As a result, it is possible to provide a semiconductor photoelectrode that absorbs light efficiently and is durable.

### Example 1

Configuration of Semiconductor Photoelectrode

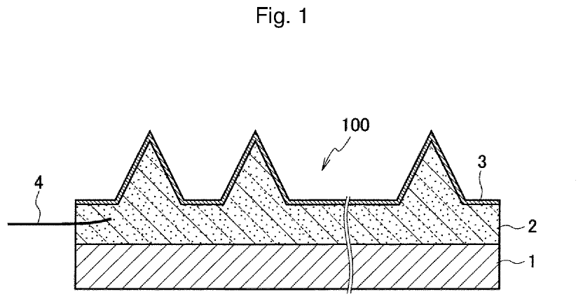

FIG. 1 is a diagram showing a cross-sectional structure of a semiconductor photoelectrode 100 according to Example 1. The semiconductor photoelectrode 100 is a semiconductor photoelectrode that is to be located in an aqueous solution to cause a decomposition reaction of the aqueous solution upon being irradiated with light, and has a plurality of protrusion structures extending in one direction. The semiconductor photoelectrode 100 includes, for example, a substrate 1, a semiconductor layer 2, a catalyst layer 3, and a wire 4.

The substrate 1 is an insulative or conductive substrate that has a flat plate shape. For example, the substrate 1 is formed using a sapphire substrate, a glass substrate, a silicon (Si) substrate, a gallium nitride (GaN) substrate, or the like.

The semiconductor layer 2 is formed on one surface of the substrate 1, and is provided with a plurality of angled protrusion structures that project in one direction (upward in FIG. 1) on the main surface, opposite the direction in which the substrate 1 is located (downward in FIG. 1), and has a photocatalytic function that is to be located in an aqueous solution to cause an oxidation reaction or a reduction reaction of the aqueous solution due to irradiation light with which the main surface is irradiated. The semiconductor layer 2 is a single or multi-layered semiconductor layer.

For example, the semiconductor layer 2 is formed using a metal oxide such as gallium nitride (GaN), n-type gallium nitride (n-GaN), titanium oxide (TiO₂), tungsten oxide (WO₃), or gallium oxide (Ga₂O₃). The semiconductor layer 2 may be formed using a compound semiconductor such as cadmium sulfide (CdS). In particular, when GaN is used for the formation, it is preferable to layer one or more nitride semiconductors (for example, an aluminum gallium nitride (AlGaN) thin film) on top of the n-GaN thin film, where the energy level at the bottom of the conduction band is larger on the negative side than that of n-GaN, to promote charge separation.

The catalyst layer 3 is a catalyst layer that is continuously laminated on the aforementioned main surface of the semiconductor layer 2, and has a catalytic function that is the function of collecting holes generated in the semiconductor layer 2 due to irradiation light (an auxiliary catalytic function that assists the photocatalytic function of the semiconductor layer 2). For example, the catalyst layer 3 is formed using nickel oxide (NiO). The catalyst layer 3 may be formed using a metal oxide obtained through heat treatment carried out after a metal that can be oxidized later such as titanium (Ti) or cobalt (Co) is formed. It is preferable that the film thickness of the catalyst layer 3 is within the range that does not interfere with the transmission of irradiation light to the semiconductor layer 2 (for example, approximately 1 nm to approximately 5 nm). Also, it is preferable that the catalyst layer 3 is laminated on the entire surface or substantially the entire surface of the aforementioned main surface that is provided with a plurality of angle structures of the semiconductor layer 2.

The wire 4 is a wire that is electrically connected to the semiconductor layer 2. For example, the wire 4 is formed using a conducting wire.

Method for Manufacturing Semiconductor Photoelectrode

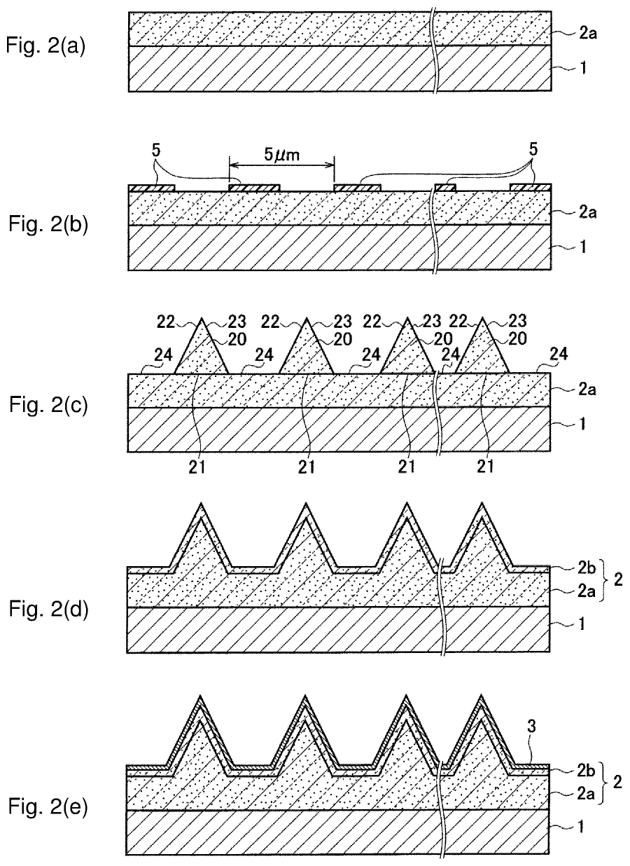

FIG. 2 is a diagram showing procedures for manufacturing the semiconductor photoelectrode 100 according to Example 1.

First Step

First, an Si-doped n-GaN thin film 2a is epitaxially grown on the sapphire (0001) surface of the sapphire substrate 1, using the metal organic chemical vapor deposition (FIG. 2(a)). The film thickness of the n-GaN thin film 2a was set to approximately 2 μm.

Second Step

Next, a silicon dioxide (SiO₂), which is commonly used as a mask for selective growth of GaN, is deposited on the surface of the n-GaN thin film 2a using sputtering, and a linear mask pattern 5 is formed using photolithography (FIG. 2(b)). The width of the mask pattern 5 was set to approximately 2 μm, and the pitch between adjacent mask patterns 5 was set to approximately 5 μm. Furthermore, the n-GaN thin film 2a is selectively grown again in mask apertures where the mask pattern 5 is not formed on the surface of the n-GaN thin film 2a (surface exposed portions of the n-GaN thin film 2a) (FIG. 2(c)).

At this time, by controlling growth conditions such as the growth temperature and the raw material supply ratio at the time of selective growth, it is possible to control the cross-sectional shape of the n-GaN thin film 2a formed through the selective growth so as to have an angled shape, a trapezoidal shape, a rectangular shape, or the like. In the present Example, a plurality of n-GaN angle structures 20 that each have an angled shape and extend upward on the sheet of the drawing are formed in a horizontal direction. A bottom surface 21 of each n-GaN angled structure 20 is a GaN(0001) surface, and the two slopes 22 and 23 thereof are GaN{10-11} surfaces. Each of the angles formed by the bottom surface 21 and the two slopes 22 and 23 was set to approximately 61.6°, and the angle formed by the two slopes 22 and 23 was set to approximately 56.8°. The height was set to approximately 0.93 μm. With this structure, the surface area is increased to be approximately twice compared to the case in which the n-GaN angle structures 20 are not provided.

Third Step

Next, on the surface of the n-GaN thin film 2a on which the plurality of n-GaN angle structures 20 have been formed, an AlGaN thin film 2b is selectively grown on each of the slopes 22 and 23 that constitute the angle structures and each of the surfaces 24 that each constitute a valley between n-GaN angle structures, using the metal organic chemical vapor deposition (FIG. 2(d)). The Al composition of the AlGaN thin film 2b was set to approximately 10% so that Al_{0.1}Ga_{0.9}N was formed. The film thickness of the AlGaN thin film 2b was set to approximately 100 nm.

Through the steps up to this point, a multi-layered semiconductor thin film 2 (the n-GaN thin film 2a and the AlGaN thin film 2b) that is provided with a plurality of angle structures projecting upward on the sheet of the drawing is formed. The sapphire substrate 1 and the semiconductor thin film 2 are composed of AlGaN/n-GaN/sapphire when viewed from the surface side.

Fourth Step

Finally, Ni is deposited on the surface of the AlGaN thin film 2b with a film thickness of approximately 1 nm, and the vapor-deposited sapphire substrate 1 is subjected to heat treatment in an atmospheric air for approximately 1 hour at approximately 290 degrees so that the NiO catalyst 3 is formed on the entire surface of the AlGaN thin film 2b (FIG. 2(e)). It was confirmed that Ni was oxidized through this heat treatment and became an NiO catalyst 3 that has a continuous film structure on the surface of the AlGaN thin film 2b. The film thickness of the NiO catalyst 3 was approximately 1.7 nm.

Method for Manufacturing Wiring Portion

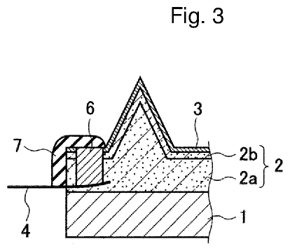

FIG. 3 is a diagram showing a cross-sectional structure of a wiring portion of the semiconductor photoelectrode 100 according to Example 1.

The substrate of the semiconductor photoelectrode 100 obtained in the above-described fourth step is cut to a size of approximately 10 mm×15 mm, and a portion of the surface thereof is peeled off with a diamond cutter to expose the n-GaN thin film 2a. Thereafter, one end of the wire 4 is inserted into the exposed portion, and the wire 4 is bonded to the n-GaN thin film 2a by bonding an indium 6 with a soldering iron. Thereafter, the indium 6 is coated with an epoxy resin 7 so that the surface of the indium 6 is not exposed. The size of the exposed portion (the portion to be irradiated with light) of the semiconductor thin film 2 was set to a size of approximately 10 mm×10 mm.

Oxidation-Reduction Reaction Test

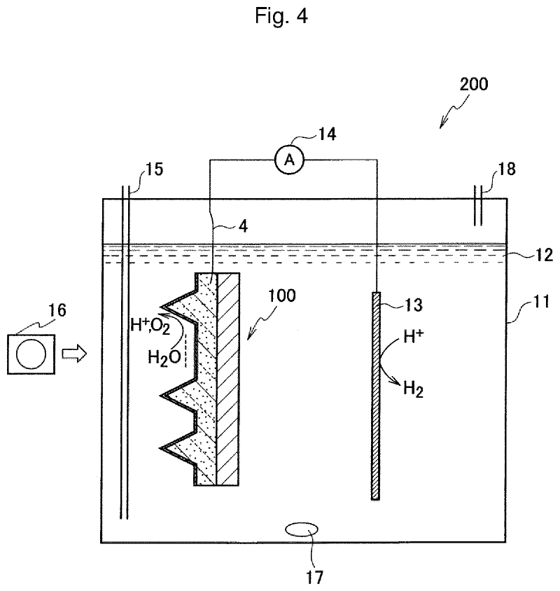

FIG. 4 is a diagram showing a configuration of an oxidation-reduction reaction apparatus 200 according to Example 1.

An oxidation-reduction reaction test was conducted using the semiconductor photoelectrode 100 with the wire 4 formed. Approximately 20 mL of a 1 M (molar) sodium hydroxide (NaOH) aqueous solution 12 serving as a solvent was put in a light transmitting cell 11, which was a quartz test tube with a content of 30 mL and an inner diameter of 20 mm. The above-described semiconductor photoelectrode 100 was immersed in the NaOH aqueous solution 12, and a Pt wire (manufactured by BAS, model number 002222) 13 serving as a counter electrode was further immersed, and the wire 4 of the semiconductor photoelectrode 100 was connected to the Pt wire 13 via an ammeter 14.

The light transmitting cell 11 was subjected to defoaming and replacement by performing bubbling with an argon gas from an input port 15 at approximately 200 mL/min for approximately 30 minutes in advance of the test, and the argon gas was pumped into the light transmitting cell 11 at approximately 20 mL/min during the test. The internal pressure of the light transmitting cell 11 was set at the atmospheric pressure (1 atm). A 300 W high-voltage xenon lamp (100 mW/cm²) adjusted to have the illuminance of sunlight was used as a light source 16 for the oxidation-reduction reaction, and the semiconductor layer-forming surface of the semiconductor photoelectrode 100 was uniformly irradiated from the outside of the light transmitting cell 11. The NaOH aqueous solution 12 was stirred at the center position of the cell bottom at a rotational speed of approximately 250 rpm, using an agitator 17 such as a rotor or stirrer.

The amount of photocurrent after light irradiation was recorded, and the gas output from the light transmitting cell 11 via an output port 18 at any given time was analyzed using gas chromatography. As a result, it was confirmed that hydrogen (H₂) and oxygen (O₂) were generated. The photocurrent density after 30 minutes was approximately 0.60 mA/cm². Furthermore, it was confirmed that the maintenance ratio of the photocurrent density was approximately 97% after 10 hours, and that the photocurrent density was maintained at approximately 80% even after 100 hours.

In the present Example, NaOH was used as an example of an aqueous solution/electrolyte. However, for example, potassium hydroxide (KOH), sulfuric acid (H₂SO₄), hydrochloric acid (HCl), sodium sulfate (Na₂SO₄), potassium bicarbonate (KHCO₃), or another electrolyte may be used.

### Example 2

A semiconductor photoelectrode 100 according to Example 2 includes the substrate 1, the semiconductor layer 2 (the n-GaN thin film 2a and the AlGaN thin film 2b), and the wire 4. According to Example 2, the catalyst layer 3 was not formed. The semiconductor photoelectrode 100 was created through the same procedures as in Example 1, except that the catalyst layer 3 was not formed, and an oxidation-reduction reaction test was conducted.

### Example 3

A semiconductor photoelectrode 100 according to Example 3 includes the substrate 1, a semiconductor layer 2 (the n-GaN thin film 2a), and the wire 4. According to Example 3, the AlGaN thin film 2b and the catalyst layer 3 are not formed. The semiconductor photoelectrode 100 was created through the same procedures as in Example 1, except that the AlGaN thin film 2b and the catalyst layer 3 were not formed, and an oxidation-reduction reaction test was conducted.

### Example 4

A semiconductor photoelectrode 100 according to Example 4 includes the substrate 1, a semiconductor layer 2 (the n-GaN thin film 2a), the catalyst layer 3, and the wire 4. According to Example 4, the AlGaN thin film 2b was not formed. The semiconductor photoelectrode 100 was created through the same procedures as in Example 1, except that the AlGaN thin film 2b was not formed, and an oxidation-reduction reaction test was conducted.

### Comparative Example 1

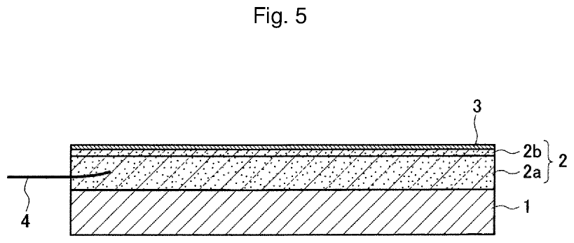

FIG. 5 is a diagram showing a cross-sectional structure of a semiconductor photoelectrode 100 according to Comparative Example 1.

In Comparative Example 1, the plurality of angle structures were not formed on the semiconductor layer 2. In Comparative Example 1, an Si-doped n-GaN thin film 2a was epitaxially grown on the sapphire (0001) surface of the sapphire substrate 1, using the metal organic chemical vapor deposition. The film thickness was set to approximately 2 μm. Next, the AlGaN thin film 2b was grown on the surface of the n-GaN thin film 2a, using the metal organic chemical vapor deposition. The Al composition of the AlGaN thin film 2b was set to approximately 10% so that Al_{0.1}Ga_{0.9}N was formed. The film thickness of the AlGaN thin film 2b was set to approximately 100 nm. Furthermore, Ni was deposited on the surface of the AlGaN thin film 2b with a film thickness of approximately 1 nm, and the vapor-deposited sapphire substrate 1 was subjected to heat treatment in an atmospheric air for approximately 1 hour at approximately 290 degrees so that the NiO catalyst 3 was formed on the entire surface of the AlGaN thin film 2b. The method for manufacturing the wire 4 and conducting the oxidation-reduction test were the same as in Example 1.

### Comparative Example 2

In Comparative Example 2, the plurality of angle structures were not formed on the semiconductor layer 2, and the catalyst layer 3 was not formed on the entire surface of the semiconductor layer 2, but a portion of the surface thereof. A semiconductor layer 2 without the plurality of angle structures on the sapphire (0001) surface of the sapphire substrate 1 was formed in the same manner as in Comparative Example 1. Furthermore, NiO catalyst 3 was formed in the form of islands on the surface of the AlGaN thin film 2b by spin-coating the surface of the AlGaN thin film 2b with a solution of MOD coating agent NiO (JAPAN PURE CHEMICAL CO., LTD.) diluted to approximately 1/200 at 500 rpm for 20 seconds, heating it at approximately 110 degrees for approximately 5 minutes to remove the solvent, and thereafter performing heat treatment on it at approximately 550 degrees for approximately 30 minutes in an atmospheric air. As a result of observation using an SEM electron microscope, it was confirmed that the diameter was approximately 10 μm and the coverage ratio (the ratio of the area covered by the NiO catalyst 3 to the surface area of the semiconductor layer 2) was approximately 1%. The methods for manufacturing the wire 4 and conducting the oxidation-reduction test were the same as in Example 1.

### Comparative Example 3

In Comparative Example 3, the plurality of angle structures were not formed on the semiconductor layer 2, and the catalyst layer 3 was not formed. The semiconductor photoelectrode 100 was created through the same procedures as in Comparative Example 1, except that the catalyst layer 3 was not formed, and an oxidation-reduction reaction test was conducted.

Evaluation of Semiconductor Photoelectrodes

Regarding Examples 1 to 4 and Comparative Examples 1 to 3, the photocurrent densities measured after 30 minutes and the maintenance ratios of each photocurrent density after 10 hours and 100 hours are shown in Table 1. The maintenance ratio of each photocurrent density is expressed as a percentage (%) of the photocurrent density after the aforementioned time, assuming that the photocurrent density after 30 minutes is 100%.

TABLE 1

| | | | | Maintenance | |
|---|---|---|---|---|---|
| | | | | ratio of | |
| | | | Photocurrent | photocurrent | |
| | | | density | density (%) | |
| | | | after 30 | After | After |
| | Semiconductor | | minutes | 10 | 100 |
| | layer | Catalyst layer | (mA/cm²) | hours | hours |
| Example 1 | AlGaN/n-GaN | NiO was formed by | 0.60 | 97 | 80 |
| | (Angle | performing heat | | | |
| | structures) | treatment on Ni (Film | | | |
| | | thickness: 1 nm) | | | |
| Example 2 | AlGaN/n-GaN | None | 0.62 | 49 | 0 |
| | (Angle | | | | |
| | structures) | | | | |
| Example 3 | n-GaN (Angle | None | 0.40 | 23 | 0 |
| | structures) | | | | |
| Example 4 | n-GaN (Angle | NiO was formed by | 0.39 | 95 | 82 |
| | structures) | performing heat | | | |
| | | treatment on Ni (Film | | | |
| | | thickness: 1 nm) | | | |
| Comparative | AlGaN/n-GaN | NiO was formed by | 0.20 | 98 | 78 |
| Example 1 | | performing heat | | | |
| | | treatment on Ni (Film | | | |
| | | thickness: 1 nm) | | | |
| Comparative | AlGaN/n-GaN | Island-shaped NiO | 0.22 | 91 | 0 |
| Example 2 | | portions were formed | | | |
| | | by performing spin- | | | |
| | | coating | | | |
| Comparative | AlGaN/n-GaN | None | 0.21 | 18 | 0 |
| Example 3 | | | | | |

From Table 1, it can be seen that the photocurrent density after 30 minutes in Examples 1 to 4 is higher than the photocurrent density after 30 minutes in any of Comparative Examples 1 to 3. It is conceivable that the angle structures provided on the surface of the semiconductor layer 2 promoted light absorption.

Furthermore, it can be understood that the light current density after 30 minutes in Examples 1 and 2 is approximately 1.5 times higher than the light current density after 30 minutes in Examples 3 and 4. It is conceivable that the electrification separation was promoted as a result of the semiconductor layer 2 having a laminated structure of AlGaN/n-GaN being formed.

When the maintenance ratios of the photocurrent densities in Example 1 and Example 2 after 100 hours are compared, the maintenance ratio in Example 1 in which the catalyst layer 3 was formed is 80%, and is kept higher than in Example 2 in which the catalyst layer 3 was not formed. It is conceivable that the catalyst layer 3 had the effect of suppressing the deterioration of the semiconductor layer 2. The same applies to the comparison between the maintenance ratios of the photocurrent densities in Example 3 and Example 4 after 100 hours.

Also, when the maintenance ratios of the photocurrent densities in Example 1 (or Comparative Example 1) and Comparative Example 2 after 100 hours are compared, the maintenance ratio was approximately 80% in the case of Example 1 (or Comparative Example 1) where the catalytic layer 3 was formed on the entire surface of the semiconductor layer 2, and 0% in the case of Comparative Example 2 where the catalytic layer 3 was formed in the form of islands. It is confirmed that the catalyst layer 3, which was formed in a dense layer on the surface of the semiconductor layer 2 using vapor deposition or the like, was more effective in suppressing the deterioration of the semiconductor layer 2.

### Modifications of Semiconductor Photoelectrode

Modification 1

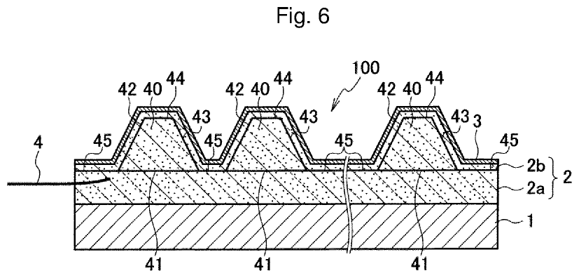

FIG. 6 is a diagram showing a cross-sectional structure of a semiconductor photoelectrode 100 according to Modification 1 of Example 1. This semiconductor photoelectrode 100 is provided with a plurality of trapezoidal structures that extend and project in one direction (upward in FIG. 6) in the form of trapezoids, in a horizontal direction.

The semiconductor photoelectrode 100 includes the sapphire substrate 1, the n-GaN thin film 2a grown on the sapphire substrate 1, extending upward direction of the sheet of the drawing, and provided with the plurality of trapezoidal structures grown in the horizontal direction and the depth direction of the sheet of the drawing, the AlGaN thin film 2b grown on the surface of the n-GaN thin film 2a, and the NiO catalyst 3 formed on the surface of the AlGaN thin film 2b.

The plurality of n-GaN trapezoidal structures 40 formed on the surface of the n-GaN thin film 2a are deposited parallel to each other in the depth direction on the n-GaN thin film 2a, and the horizontal cross sections thereof are trapezoidal. Each n-GaN trapezoidal structure 40 includes a slope 42 that extends in the depth direction in contact with the n-GaN thin film 2a, a slope 43 that extends in the depth direction in contact with the n-GaN thin film 2a, and an upper bottom surface 44 that extends in the depth direction in parallel with a lower bottom surface 41 of the n-GaN trapezoidal structure 40. The AlGaN thin film 2b is grown on the slope 42, the slope 43, the upper bottom surface 44 of each n-GaN trapezoidal structure 40, and on the surfaces 45 that form valleys between the trapezoidal structures of the n-GaN trapezoidal structures 40.

Modification 2

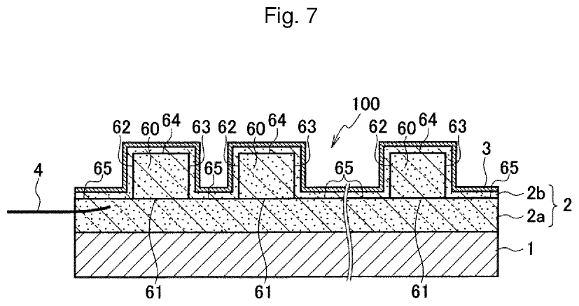

FIG. 7 is a diagram showing a cross-sectional structure of a semiconductor photoelectrode 100 according to Modification 2 of Example 1. This semiconductor photoelectrode 100 is provided with a plurality of rectangular structures that extend and project in one direction (upward in FIG. 7) in the form of rectangles, in a horizontal direction.

The semiconductor photoelectrode 100 includes the sapphire substrate 1, the n-GaN thin film 2a grown on the sapphire substrate 1, extending upward direction of the sheet of the drawing, and provided with the plurality of rectangular structures grown in the horizontal direction and the depth direction of the sheet of the drawing, the AlGaN thin film 2b grown on the surface of the n-GaN thin film 2a, and the NiO catalyst 3 formed on the surface of the AlGaN thin film 2b.

The plurality of n-GaN rectangular structures 60 formed on the surface of the n-GaN thin film 2a are deposited parallel to each other in the depth direction on the n-GaN thin film 2a, and the horizontal cross sections thereof are rectangular. Each of the n-GaN rectangular structures 60 includes a vertical surface 62 that extends in the depth direction in contact with the n-GaN thin film 2a, a vertical surface 63 that extends in the depth direction in contact with the n-GaN thin film 2a, and an upper surface 64 that extends in the depth direction in parallel with a lower bottom surface 61 of the n-GaN rectangular structure 60. The AlGaN thin film 2b is grown on the vertical surface 62, the vertical surface 63, the upper surface 64 of each n-GaN rectangular structure 60, and on the surfaces 65 that form valleys between the rectangular structures of the n-GaN rectangular structures 60.

Modification 3

The semiconductor photoelectrode 100 is not limited to the angle structures, the trapezoidal structures, or the rectangular structures. The semiconductor photoelectrode 100 need only be provided with a plurality of protrusion structures such as oblong structures, square structures, semicircular structures, staircase structures, or the like. Also, the semiconductor photoelectrode 100 may be provided with a combination of a plurality of structures that have difference cross-sectional shapes or side surface shapes, such as angle structures and trapezoidal structures. Due to such protrusion structures, the surface area of the semiconductor layer 2 are increased, and light can be efficiently absorbed.

### Others

In the oxidation-reduction reaction test in Example 1, the oxidation-reduction target substance and the reduction target substance were water, and the generation of oxygen caused by the oxidation reaction of water and the generation of hydrogen caused by the reduction of protons generated as a result of the oxidation of water were described as examples. However, the oxidation-reduction target substance is not limited to water, and the semiconductor photoelectrode 100 according to the present invention can also be used when the reduction reaction is carried out to generate a hydrocarbon or the like of carbon monoxide, formic acid, methanol, or methane, using carbon dioxide as the reduction target substance. Also, the way in which the oxidation-reduction reaction test is conducted is not limited to Example 1, and the same effects can be achieved by forming a reaction cell that includes an electrolytic solution, an oxidation electrode, and a reduction electrode capable of advancing a photoelectrochemical reaction, and using sunlight as a light source.

### Effects of Examples

According to the present examples, a semiconductor photoelectrode 100 that is to be located in an aqueous solution to cause a decomposition reaction of the aqueous solution upon being irradiated with light includes: a semiconductor layer 2 that is formed on an insulative or conductive substrate 1 and is provided with a plurality of protrusion structures that protrude in one direction that is opposite a direction in which the substrate is located; a catalyst layer 3 that is continuously laminated on the surface of the semiconductor layer 2; and a wire 4 that is electrically connected to the semiconductor layer 2. Therefore, it is possible to provide a semiconductor photoelectrode 100 that can suppress deterioration and improve light absorption efficiency.

That is to say, due to a plurality of protrusion structures formed on the surface of the semiconductor layer 2, the area of the decomposition reaction site (the oxidation reaction site and the reduction reaction site) is increased and efficient light absorption can be realized, and the number of electrons and holes generated due to light irradiation is increased. Also, due to the catalyst layer 3 formed on the semiconductor layer 2, the holes generated in the semiconductor layer 2 due to light irradiation is collected by the catalyst layer 3, and oxidative deterioration of the semiconductor layer 2 can be suppressed. Therefore, the rate of hydrogen production does not decline with the light irradiation time, and a stable high photocurrent can be obtained. As a result, it is possible to provide a semiconductor photoelectrode that absorbs light efficiently and is durable.

Also, according to the present examples, the semiconductor layer 2 is constituted by multiple layers in which a plurality of nitride semiconductors that include a layer of n-type gallium nitride formed on the substrate 1 are layered. Therefore, light absorption efficiency can be further improved.

Also, according to the present examples, the catalyst layer 3 is laminated on the entire surface of the semiconductor layer 2 on which a plurality of protrusion structures are provided. Therefore, efficiency in which the catalyst layer 3 collects holes generated in the semiconductor layer 2 due to irradiation light is increased, the oxidative deterioration of the semiconductor layer 2 can be suppressed more reliably, and high durability can be obtained.

### REFERENCE SIGNS LIST

1 Substrate
2 Semiconductor layer, Semiconductor thin film
2a n-GaN thin film
2b AlGaN thin film
3 Catalyst layer
4 Wire
5 Mask pattern
6 Indium
7 Epoxy resin
11 Light transmitting cell
12 NaOH aqueous solution
13 Pt wire
14 Ammeter
15 Input port
16 Light source
17 Agitator
18 Output port
100 Semiconductor photoelectrode
200 Oxidation-reduction reaction apparatus

1. A semiconductor photoelectrode that is to be located in an aqueous solution to cause a decomposition reaction of the aqueous solution upon being irradiated with light, the semiconductor photoelectrode comprising:
a semiconductor layer that is formed on an insulative or conductive substrate and is provided with a plurality of protrusion structures that protrude in one direction that is opposite a direction in which the substrate is located;
a catalyst layer that is continuously laminated on the surface of the semiconductor layer; and
a wire that is electrically connected to the semiconductor layer.

2. The semiconductor photoelectrode according to claim 1,
wherein the plurality of protrusion structures of the semiconductor layer are angle structures that extend in the one direction.

3. The semiconductor photoelectrode according to claim 1,
wherein the plurality of protrusion structures of the semiconductor layer are trapezoidal structures that extend in the one direction.

4. The semiconductor photoelectrode according to claim 1,
wherein the plurality of protrusion structures of the semiconductor layer are rectangular structures that extend in the one direction.

5. The semiconductor photoelectrode according to claim 1,
wherein the semiconductor layer is constituted by a single layer of n-type gallium nitride.

6. The semiconductor photoelectrode according to claim 1,
wherein the semiconductor layer is constituted by multiple layers in which a plurality of nitride semiconductors that include a layer of n-type gallium nitride formed on the substrate are layered.

7. The semiconductor photoelectrode according to claim 1,
wherein the catalyst layer is laminated on the entire surface of the semiconductor layer on which the plurality of protrusion structures are provided.

8. The semiconductor photoelectrode according to claim 2,
wherein the plurality of protrusion structures of the semiconductor layer are trapezoidal structures that extend in the one direction.

9. The semiconductor photoelectrode according to claim 2,
wherein the plurality of protrusion structures of the semiconductor layer are rectangular structures that extend in the one direction.

10. The semiconductor photoelectrode according to claim 3,
wherein the plurality of protrusion structures of the semiconductor layer are rectangular structures that extend in the one direction.

11. The semiconductor photoelectrode according to claim 2,
wherein the semiconductor layer is constituted by a single layer of n-type gallium nitride.

12. The semiconductor photoelectrode according to claim 3,
wherein the semiconductor layer is constituted by a single layer of n-type gallium nitride.

13. The semiconductor photoelectrode according to claim 4,
wherein the semiconductor layer is constituted by a single layer of n-type gallium nitride.

14. The semiconductor photoelectrode according to claim 2,
wherein the semiconductor layer is constituted by multiple layers in which a plurality of nitride semiconductors that include a layer of n-type gallium nitride formed on the substrate are layered.

15. The semiconductor photoelectrode according to claim 3,
wherein the semiconductor layer is constituted by multiple layers in which a plurality of nitride semiconductors that include a layer of n-type gallium nitride formed on the substrate are layered.

16. The semiconductor photoelectrode according to claim 4,
wherein the semiconductor layer is constituted by multiple layers in which a plurality of nitride semiconductors that include a layer of n-type gallium nitride formed on the substrate are layered.

17. The semiconductor photoelectrode according to claim 2,
wherein the catalyst layer is laminated on the entire surface of the semiconductor layer on which the plurality of protrusion structures are provided.

18. The semiconductor photoelectrode according to claim 3,
wherein the catalyst layer is laminated on the entire surface of the semiconductor layer on which the plurality of protrusion structures are provided.

19. The semiconductor photoelectrode according to claim 4,
wherein the catalyst layer is laminated on the entire surface of the semiconductor layer on which the plurality of protrusion structures are provided.

20. The semiconductor photoelectrode according to claim 5,
wherein the catalyst layer is laminated on the entire surface of the semiconductor layer on which the plurality of protrusion structures are provided.
